(19) United States
(12) Patent Application Publication
(10) Pub. No.: US 2026/0018502 A1
(43) Pub. Date: Jan. 15, 2026

(54) SEMICONDUCTOR DEVICE

(71) Applicant: Samsung Electronics Co., Ltd., Suwon-si (KR)

(72) Inventors: JIEUN PARK, Suwon-si (KR); DAHEE KIM, Suwon-si (KR); WOOSEOK PARK, Suwon-si (KR); MINKYU KIM, Suwon-si (KR); MYUNGDO CHO, Suwon-si (KR); YOUNCHAN CHOI, Suwon-si (KR); JAEYOUNG CHOI, Suwon-si (KR)

(21) Appl. No.: 19/011,999

(22) Filed: Jan. 7, 2025

(30) Foreign Application Priority Data
Jul. 12, 2024 (KR) 10-2024-0092191
Aug. 22, 2024 (KR) 10-2024-0112747

(51) Int. Cl. H01L 23/498; H01L 23/00

(52) U.S. Cl. CPC H01L 23/49816; H01L 23/49827; H01L 24/14; H01L 2224/1403; H01L 2224/1411

(57) ABSTRACT

A semiconductor device including a redistribution substrate and a semiconductor chip on the redistribution substrate. The redistribution substrate includes an under-bump pad on a bottom surface of the redistribution substrate. The under-bump pad comprises a first pad part, a second pad part on the first pad part, and a via part that protrudes from the second pad part and contacts the first pad part. The first pad part has a first width in a first direction parallel to a top surface of the redistribution substrate. The second pad part has a second width in the first direction. The second width is greater than the first width.

### CROSS-REFERENCE TO RELATED APPLICATIONS

This application claims priority under 35 U.S.C § 119 to Korean Patent Applications No. 10-2024-0092191 filed on Jul. 12, 2024 and No. 10-2024-0112747 filed on Aug. 22, 2024 in the Korean Intellectual Property Office, the disclosures of which are hereby incorporated by reference in their entirety.

### BACKGROUND

The technology relates to a semiconductor package, and more particularly, to a semiconductor package including an under-bump pad.

With the development of electronic industry, electronic products have increasing demands for high performance, high speed, and compact size. To meet the trend, there has recently been developed a packaging technology in which a plurality of semiconductor chips are mounted in a single package.

A semiconductor package is provided to implement an integrated circuit chip to qualify for use in electronic products. Typically, in the semiconductor package, a semiconductor chip is mounted on a printed circuit board (PCB) and bonding wires or bumps are used to electrically connect the semiconductor chip to the printed circuit board. With the recent development of the electronic industry, the semiconductor package is variously developed to reach the goals of compact size, low weight, and/or low manufacturing cost. In addition, many kinds of semiconductor packages have been introduced with the expansion of their application field such as high-capacity mass storage devices.

### SUMMARY

It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably in describing each material, layer, region, electrode, pad, pattern, structure or process.

The terms “comprises,” “comprising,” “includes” and/or “including,” when used herein, specify the presence of stated elements, but do not preclude the presence of additional elements. The term “and/or” includes any and all combinations of one or more of the associated listed items.

The term “connected” may be used herein to refer to a physical and/or electrical connection.

A first element described as “on” a second element may be disposed directly on the second element (e.g., in contact with the second element) or indirectly on the second element (e.g., with an intervening element interposed between the first and second elements). When components or layers are referred to herein as “directly” on, or “in direct contact” or “directly connected,” no intervening components or layers are present.

The terms “surround” or “cover” or “fill” as may be used herein may not require completely surrounding or covering or filling the described elements or layers, but may, for example, refer to partially surrounding or covering or filling the described elements or layers, for example, with one or more discontinuities therein.

A first element that “covers” a second element may or may not be in contact with the second element.

For the purpose of explanation, certain dimensions of components are described herein as a component's “width” and the component's “length”. Unless otherwise specified, the use of these terms is not intended to mean that the width of the component is necessarily less than its length.

Some embodiments of the present technology provide a redistribution substrate with improved structural stability and a semiconductor package including the same.

Objects of the present technology are not limited to those mentioned above, and other objects which have not been mentioned above will be clearly understood to those skilled in the art from the following description.

According to some embodiments of the present technology, a semiconductor package may comprise: a redistribution substrate; and a semiconductor chip on the redistribution substrate. The redistribution substrate may comprise an under-bump pad on a bottom surface of the redistribution substrate. The under-bump pad may comprise: a first pad part; a second pad part on the first pad part; and a via part that protrudes from the second pad part and contacts the first pad part. The first pad part may have a first width in a first direction parallel to a top surface of the redistribution substrate. The second pad part may have a second width in the first direction. The second width may be greater than the first width.

According to some embodiments of the present technology, a semiconductor package may comprise: a redistribution substrate; and a semiconductor chip on the redistribution substrate. The redistribution substrate may comprise: a plurality of dielectric layers; a plurality of wiring patterns in the dielectric layer; and an under-bump pad on a bottom surface of the redistribution substrate. The wiring patterns may comprise: a line part; and a first via part that protrudes from the line part. The under-bump pad may comprise: a first pad part; a second pad part on the first pad part; and a second via part between the first pad part and the second pad part. The second pad part may be in contact with the first via part. A thickness of the first pad part may be greater than a thickness of the line part. The first via part may have a first via part width in a first direction parallel to a top surface of the redistribution substrate. The second via part may have a second via part width in the first direction. The second via part width may be greater than the first via part width.

According to some embodiments of the present technology, a semiconductor package may comprise: a package substrate; a redistribution substrate on the package substrate; a chip stack on the redistribution substrate; and a logic chip on the redistribution substrate and spaced apart in a first direction from the chip stack. The first direction may be parallel to a top surface of the package substrate. The redistribution substrate may comprises: a plurality of dielectric layers; a plurality of wiring patterns in the plurality of dielectric layer; and a plurality of under-bump pads spaced apart in the first direction from each other on a bottom surface of the redistribution substrate. The wiring patterns may comprise: a line part; and a first via part that protrudes from the line part. Each of the under-bump pads may comprise: a first pad part; a second pad part on the first pad part; and a second via part that protrudes from the second pad part and contacts the first pad part. A distance in the first direction between the first pad parts may be greater than a distance in the first direction between the second pad parts.

### BRIEF DESCRIPTION OF DRAWINGS

FIG. 1 illustrates a plan view showing a semiconductor package according to some embodiments of the present technology.

FIG. 2 illustrates a cross-sectional view taken along line A-A′ of FIG. 1.

FIG. 3A illustrates an enlarged view showing section CU1 of FIG. 2.

FIG. 3B illustrates an enlarged view showing section CU2 of FIG. 2.

FIG. 4 illustrates a bottom view showing an under-bump pad according to some embodiments of the present technology.

FIG. 5A illustrates a bottom view showing an under-bump pad according to some embodiments of the present technology.

FIG. 5B illustrates a bottom view showing an under-bump pad according to some embodiments of the present technology.

FIG. 5C illustrates a bottom view showing an under-bump pad according to some embodiments of the present technology.

FIG. 5D illustrates a bottom view showing an under-bump pad according to some embodiments of the present technology.

FIG. 5E illustrates a bottom view showing an under-bump pad according to some embodiments of the present technology.

FIGS. 6, 7, 8, 9, and 10 illustrate cross-sectional views showing a method of fabricating a semiconductor package according to some embodiments of the present technology.

### DETAILED DESCRIPTION OF EMBODIMENTS

The following will now describe in detail some embodiments of the present technology with reference to the accompanying drawings.

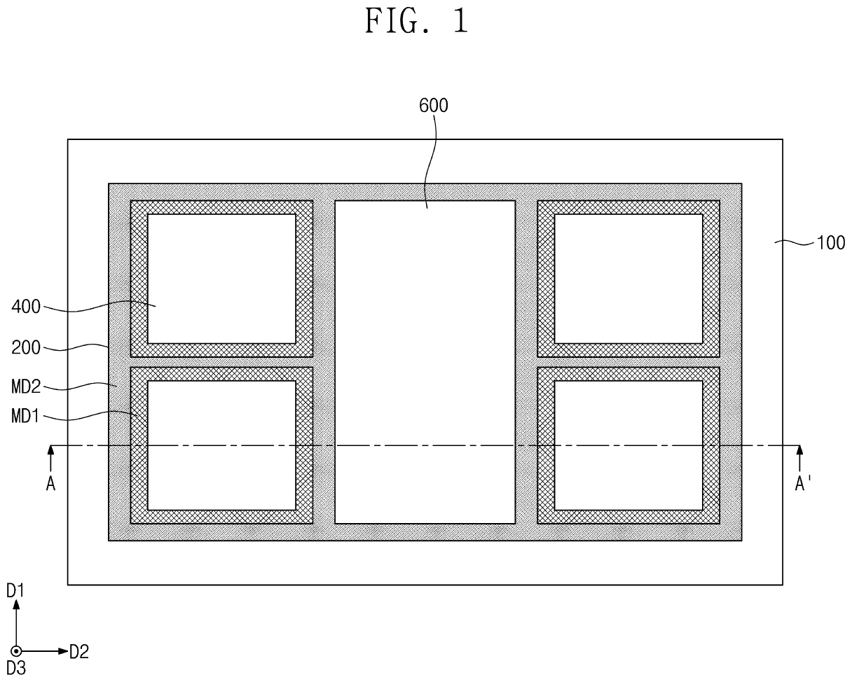

Referring to FIGS. 1 to 4, a semiconductor package 1 according to some embodiments of the present technology may include a package substrate 100, a redistribution substrate 200, a chip stack 400, and a logic chip 600.

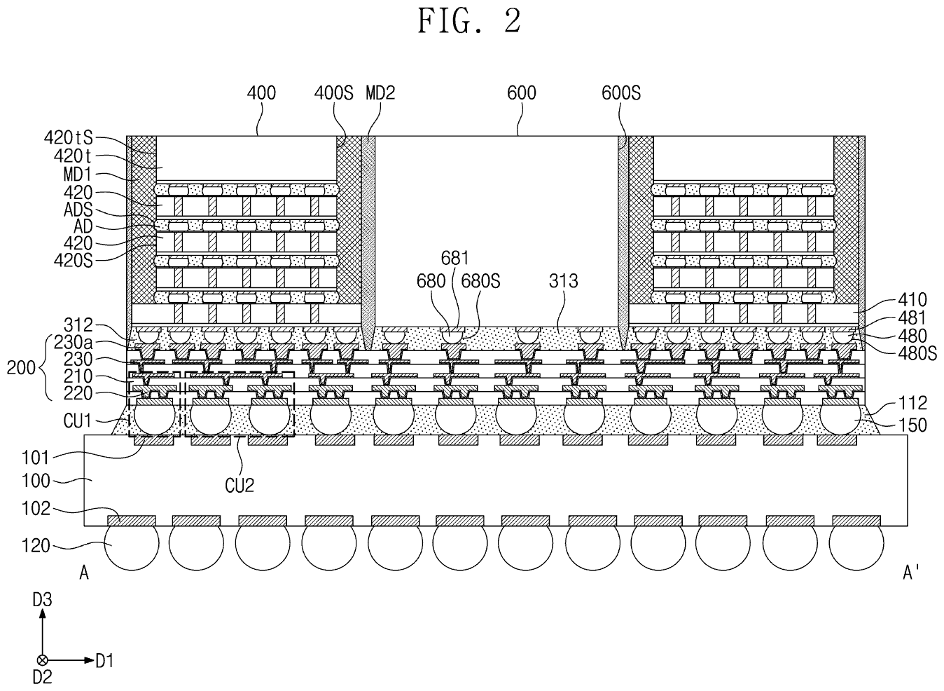

The package substrate 100 may be, for example, a printed circuit board (PCB). The package substrate 100 may include upper substrate pads 101 provided on a top surface thereof and lower substrate pads 102 provided on a bottom surface thereof. As will be appreciated from FIG. 2, for example, in some embodiments, the upper substrate pads 101 may be embedded or recessed into a top surface of the package substrate 100. Similarly, in some embodiments, the lower substrate pads 102 may be embedded or recessed into a bottom surface of the package substrate 100.

External connection terminals 120 may be correspondingly disposed on the lower substrate pads 102. The external connection terminals 120 may be electrically connected through the lower substrate pads 102 to the package substrate 100. The external connection terminals 120 may include solder balls or solder bumps. The external connection terminals 120 may each be an alloy that includes at least one selected from tin (Sn), silver (Ag), copper (Cu), nickel (Ni), bismuth (Bi), indium (In), antimony (Sb), and cerium (Ce).

The redistribution substrate 200 may be disposed on the package substrate 100. The redistribution substrate 200 may include a plurality of wiring dielectric layers 210, under-bump pads 220, and wiring patterns 230 that are stacked on each other. Although not shown, the redistribution substrate 200 may further include circuit patterns that electrically connect the chip stack 400 and the logic chip 600 which will be discussed below.

The wiring dielectric layers 210 may include an organic material, such as a photo-imageable dielectric (PID). The photo-imageable dielectric may be a polymer. The photo-imageable dielectric may include, for example, at least one selected from photosensitive polyimide, polybenzoxazole, phenolic polymers, and benzocyclobutene polymers. FIG. 2 depicts boundaries between the wiring dielectric layers 210, but the present technology is not limited thereto. According to some embodiments, indistinct interfaces may be present between neighboring wiring dielectric layers 210.

In this description, the first direction D1 may be defined to refer to a direction parallel to the top surface of the package substrate 100. The second direction D2 may be defined to refer to a direction parallel to the top surface of the package substrate 100 and orthogonal to the first direction D1. A third direction D3 may be defined to refer to a direction perpendicular to the top surface of the package substrate 100 and each of the first and second directions D1, D2.

The under-bump pad 220 may be provided on a bottom surface of the redistribution substrate 200. A plurality of under-bump pads 220 may be provided spaced apart from each other in the first direction D1 and/or the second direction D2.

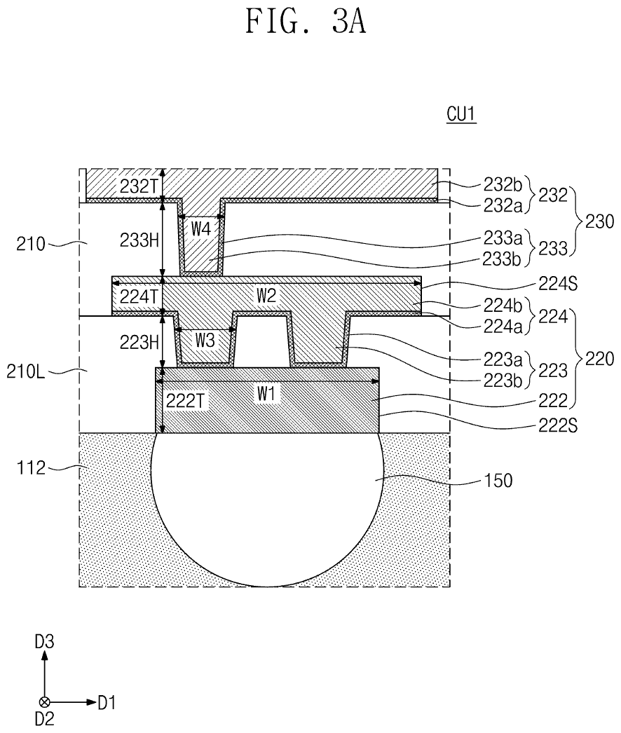

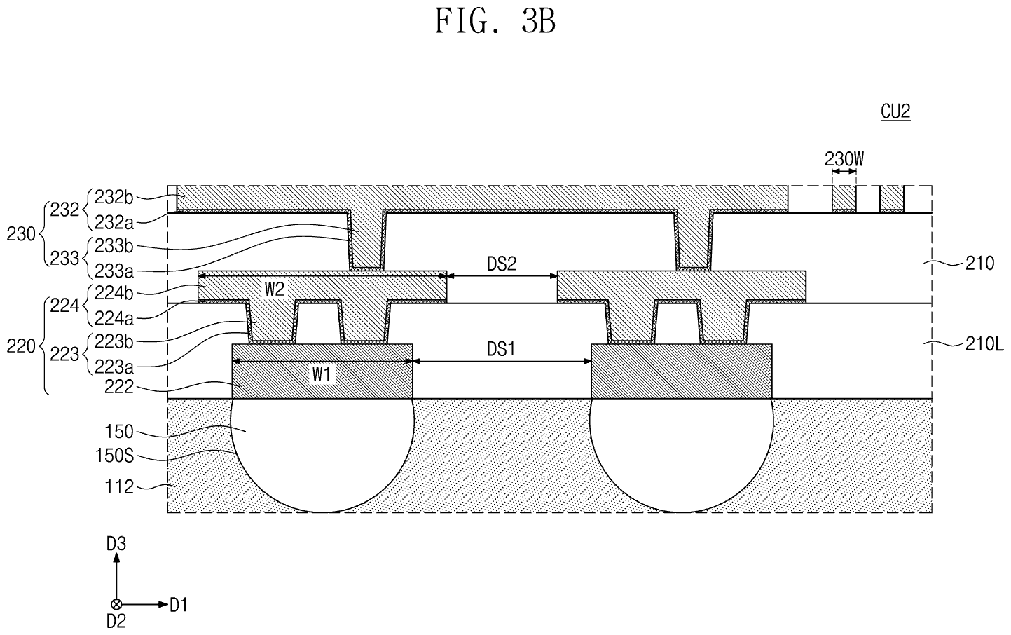

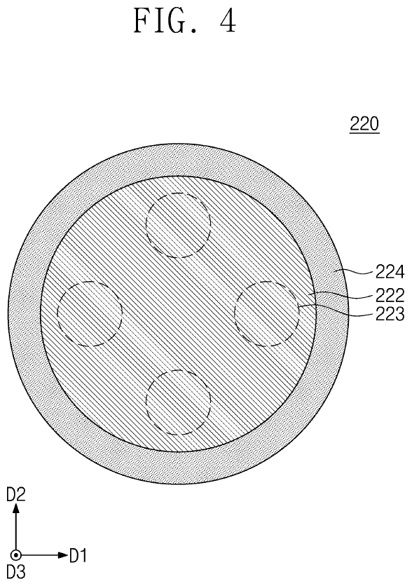

Referring to FIGS. 3A and 4, the under-bump pad 220 may include a first pad part 222, a second pad part 224 on the first pad part 222, and a second via part 223 interposed between the first pad part 222 and the second pad part 224.

When viewed in plan, the first pad part 222 may be disposed inside the second pad part 224. In other words, when viewed from the top down (i.e., along the third direction D3), the second pad part 224 may entirely overlap the first pad part 222. For example, when viewed in plan, a lateral surface 224S of the second pad part 224 may surround a lateral surface 222S of the first pad part 222. The lateral surface 222S of the first pad part 222 may be disposed more inwardly than the lateral surface 224S of the second pad part 224.

The first pad part 222 may be provided on a bottom surface of a lowermost one 210L of the plurality of wiring dielectric layers 210. The second pad part 224 may be provided on a top surface of the lowermost wiring dielectric layer 210L.

The second via part 223 may protrude downwardly from the second pad part 224 to penetrate the lowermost wiring dielectric layer 210L. The second via part 223 may be in contact with a top surface of the first pad part 222. When viewed in plan, a plurality of second via parts 223 may be provided in the first pad part 222. In other words, when viewed from the top down (i.e., along the third direction D3), a plurality of second via parts 223 may be entirely overlapped by the first pad part 222. For example, a plurality of second via parts 223 may be provided spaced apart from each other along a direction cross to the first direction D1 and the second direction D2.

The first pad part 222 may have a first width W1 (See FIG. 3A) in the first direction D1. The second pad part 224 may have a second width W2 (See FIG. 3A) in the first direction D1. The second width W2 may be greater than the first width W1. The second width W2 may be about 1.1 times to about 2 times the first width W1. For example, the first width W1 may range from about 80 μm to about 110 μm. The second width W2 may range from about 88 μm to about 220 μm.

The second via part 223 may have a third width W3 (See FIG. 3A), which may be referred to herein as a “second via part width”, in the first direction D1. The third width W3 may decrease with decreasing distance from the first pad part 222. The third width W3 may range from about 15 μm to about 20 μm.

A thickness 222T of the first pad part 222 may be greater than a thickness 224T of the second pad part 224. The thickness 222T of the first pad part 222 may range from about 4 μm to about 10 μm. The thickness 224T of the second pad part 224 may range from about 3 μm to about 5 μm.

A sum of the thickness 222T of the first pad part 222 and a height 223H of the second via part 223 may be substantially the same as a thickness of the wiring dielectric layer 210. The height 223H of the second via part 223 may range, for example, from about 3 μm to about 5 μm.

The second via part 223 may include a first seed pattern 223a and a first conductive pattern 223b on the first seed pattern 223a. The second pad part 224 may include a second seed pattern 224a and a second conductive pattern 224b on the second seed pattern 224a. A bottom surface of the first seed pattern 223a may be in contact with the first pad part 222. The first seed pattern 223a and the second seed pattern 224a may include at least one selected from copper, titanium, tungsten, and nickel. The first pad part 222, the first conductive pattern 223b, and the second conductive pattern 224b may include, for example, copper.

The wiring patterns 230 may be provided in the wiring dielectric layer 210. The wiring patterns 230 may be provided on the under-bump pads 220. The wiring patterns 230 may include a line part 232 and a first via part 233 that are integrally connected into a single unitary piece. The line part 232 may be a component for horizontal connection in the redistribution substrate 200. The first via part 233 may be a component for vertical connection of the wiring patterns 230 in the wiring dielectric layers 210. The first via part 233 may penetrate the wiring dielectric layer 210 to come into connection with the line part 232 of another wiring pattern 230 disposed thereunder or the second pad part 224 of the under-bump pad 220 disposed thereunder.

The thickness 222T of the first pad part 222 may be greater than a thickness 232T of the line part 232. The thickness 232T of the line part 232 may range, for example, from about 2 μm to about 4 μm.

The first via part 233 may have a fourth width W4, which may be referred to herein as a “first via part width”, in the first direction D1. The third width W3 of the second via part 223 may be greater than the fourth width W4 of the first via part 233. The fourth width W4 may decrease with decreasing distance from the first pad part 222. The fourth width W4 may range, for example, from about 4 μm to about 8 μm.

The line part 232 may include a third seed pattern 232a and a third conductive pattern 232b on the third seed pattern 232a. The first via part 233 may include a fourth seed pattern 233a and a fourth conductive pattern 233b on the fourth seed pattern 233a. The third seed pattern 232a and the fourth seed pattern 233a may include at least one selected from copper, titanium, tungsten, and nickel. The third conductive pattern 232b and the fourth conductive pattern 233b may include, for example, copper.

The wiring patterns 230 may include wiring pads 230a. The wiring pads 230a may be portions of an uppermost wiring pattern 230 disposed at top of the redistribution substrate 200. The wiring pads 230a may have their top surfaces that protrude from a top surface of the redistribution substrate 200. The wiring pads 230a may be connected to the wiring patterns 230 disposed thereunder.

Referring to FIGS. 2 and 3B, a distance DS1 in the first direction D1 between the first pad parts 222 included in different under-bump pads 220 may be greater than a distance DS2 in the first direction D1 between the second pad parts 224.

At least one of the wiring patterns 230 may include a plurality of first via parts 233 that protrude from the line part 232. The first via parts 233 may be correspondingly in contact with the second pad parts 224 included in different under-bump pads 220. In some embodiments, a width 230W of the wiring patterns 230 may be less than the first width W1 and the second width W2.

First connection terminals 150 may be disposed between the package substrate 100 and the redistribution substrate 200. The first connection terminals 150 may be correspondingly provided on the under-bump pads 220 and the upper substrate pads 101. For example, the first connection terminals 150 may be provided on the first pad parts 222. The first connection terminals 150 may each be an alloy that includes at least one selected from tin (Sn), silver (Ag), copper (Cu), nickel (Ni), bismuth (Bi), indium (In), antimony (Sb), and cerium (Ce).

The package substrate 100 may be provided thereon with a first underfill pattern 112 that coves a lateral surface 150S of each of the first connection terminals 150. The first underfill pattern 112 may include a dielectric material such as an epoxy resin.

On the redistribution substrate 200, the chip stack 400 and the logic chip 600 may be disposed spaced apart from each other in the first direction D1. The chip stack 400 may be a first chip stack and a plurality of chip stacks 400 may be provided spaced apart in the first direction D1 from each other across the logic chip 600. A plurality of chip stacks 400 may be provided spaced apart in the second direction D2 from each other. The number and arrangement of the chip stack 400 and the logic chip 600 may be variously changed depending on design. In this disclosure, the chip stack 400 may be called a chip structure or a high bandwidth memory. The chip stack 400 may include a first semiconductor chip 410, second semiconductor chips 420, 420t disposed on the first semiconductor chip 410, and a first molding layer MD1. In this disclosure, the first semiconductor chip 410 may be called a base chip, and the second semiconductor chips 420, 420t may be called memory chips.

The base chip 410 may be a logic chip. The base chip 410 may be, for example, a memory controller.

The memory chips 420, 420t may be stacked in the third direction D3 on the base chip 410. The memory chips 420, 420t may be the same kind of semiconductor chip having the same circuit. The memory chips 420, 420t may each be one of DRAM and NAND Flash.

All of the base chip 410 and the memory chips 420, 420t may include a circuit layer. The base chip 410 and the memory chips 420 may include through vias or electrodes. The memory chip 420t positioned at top of the memory chips 420, 420t may not include through vias therein. According to some embodiments, differently from those shown, the uppermost memory chip 420t may include through vias. The through vias of the base chip 410 may be connected through micro-bumps to the through vias of the memory chip 420 that neighbors the base chip 410. The through vias of neighboring memory chips 420 may be connected to each other through micro-bumps.

Adhesion layers AD may be interposed between the base chip 410 and its neighboring memory chip 420 and between neighboring memory chips 420. The adhesion layers AD may each be, for example, a non-conductive film (NCF) including polymer.

The first molding layer MD1 may cover a top surface of the base chip 410, lateral surfaces 420S, 420tS of the memory chips 420, 420t, and lateral surfaces ADS of the adhesion layers AD (See FIG. 2). A top surface of the uppermost memory chip 420t may be exposed from the first molding layer MD1. The first molding layer MD1 may include a dielectric material such as an epoxy molding compound (EMC).

Second connection terminals 480 may be disposed under the base chip 410. For example, the second connection terminals 480 may be correspondingly disposed on some of the wiring pads 230a and first chip pads 481 on a lower portion of the base chip 410. The second connection terminals 480 may each be an alloy that includes at least one selected from tin (Sn), silver (Ag), copper (Cu), nickel (Ni), bismuth (Bi), indium (In), antimony (Sb), and cerium (Ce). A second underfill pattern 312 may cover lateral surfaces 480S (See FIG. 2) of the second connection terminals 480. The second underfill pattern 312 may include a dielectric material such as an epoxy resin.

The logic chip 600 may be, for example, one of a central processing unit (CPU), a graphic processing unit (GPU), or an application specific integrated circuit (ASIC).

Third connection terminals 680 may be disposed under the logic chip 600. For example, the third connection terminals 680 may be correspondingly disposed on some of the wiring pads 230a and second chip pads 681 on a lower portion of the logic chip 600. The third connection terminals 680 may each be an alloy that includes at least one selected from tin (Sn), silver (Ag), copper (Cu), nickel (Ni), bismuth (Bi), indium (In), antimony (Sb), and cerium (Ce). A third underfill pattern 313 may cover lateral surfaces 680S (See FIG. 2) of the third connection terminals 680. The third underfill pattern 313 may include a dielectric material such as an epoxy resin.

A second molding layer MD2 may be disposed on the redistribution substrate 200. The second molding layer MD2 may cover a top surface of the redistribution substrate 200, a lateral surface 400S of the chip stack 400, and a lateral surface 600S of the logic chip 600. The second molding layer MD2 may include a dielectric material such as an epoxy molding compound (EMC).

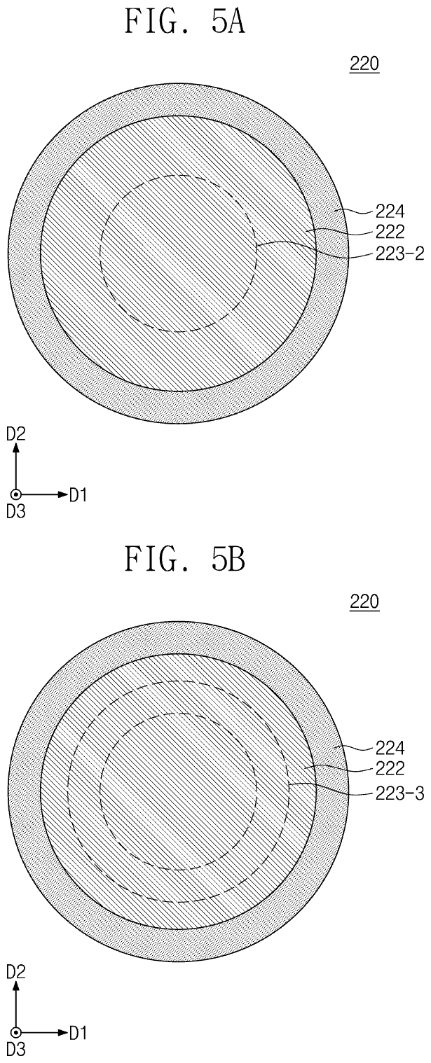

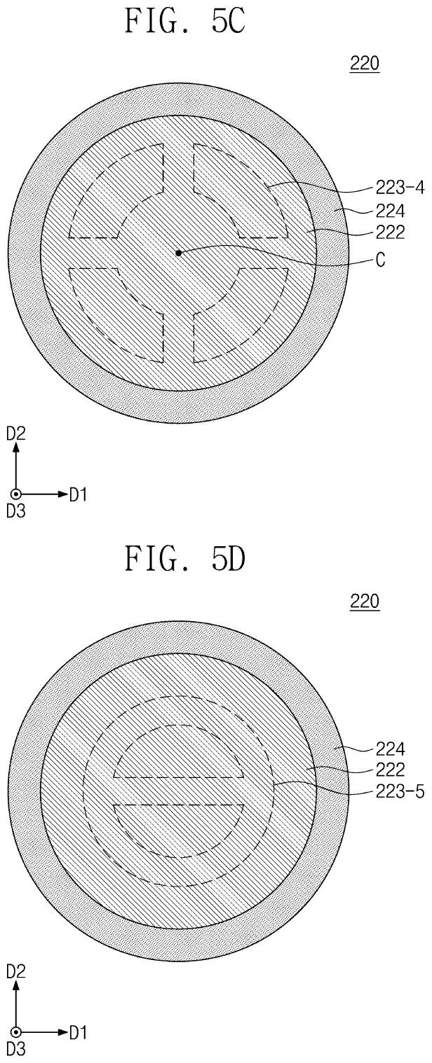

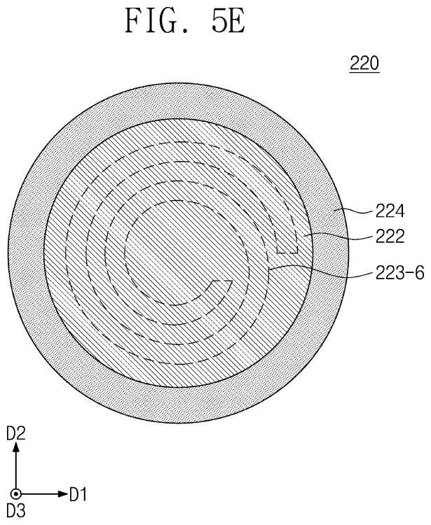

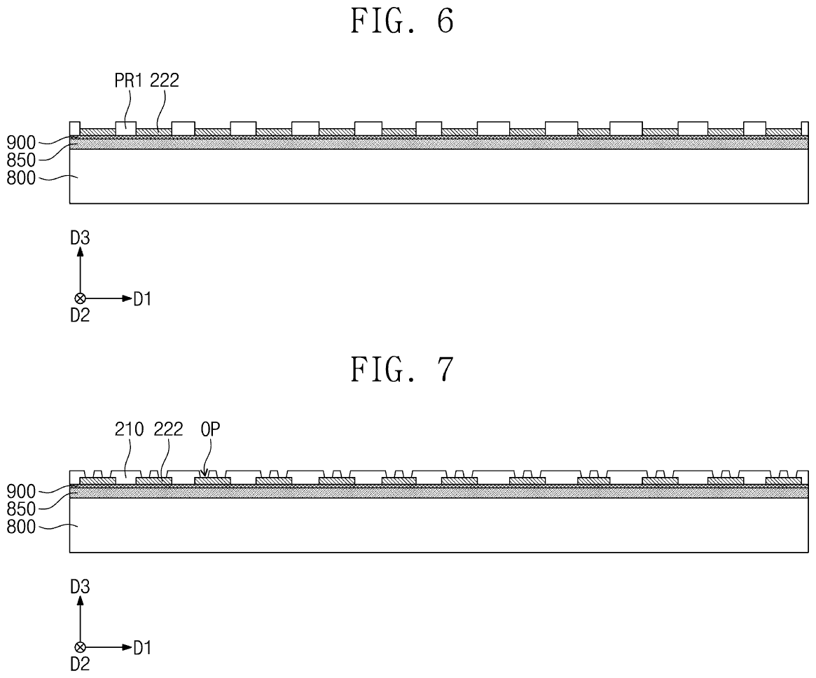

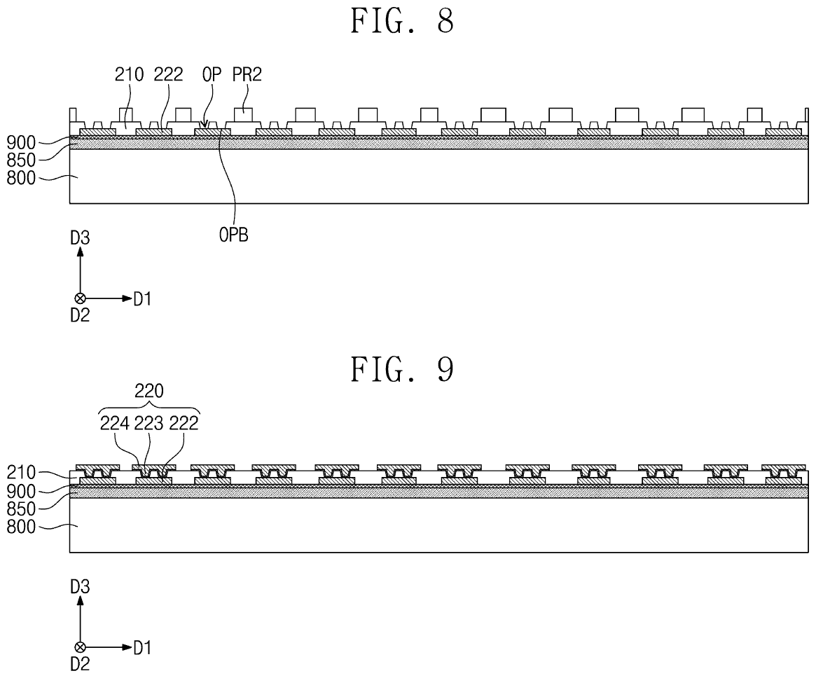

Referring to FIG. 5A, the under-bump pad 220 according to some embodiments of the present technology may include one second via part 223-2. For example, differently from the under-bump pad 220 including a plurality of second via parts 223 as shown in FIG. 4, the under-bump pad 220 according to an embodiment of FIG. 5A may include a single second via part 223-2. A size of the second via part 223-2 is not limited to that shown in FIG. 5A, and may become increased or reduced.

Referring to FIG. 5B, the second via part 223-3 of the under-bump pad 220 according to an embodiment of the present technology may have an annular shape when viewed in plan. For example, when viewed in plan, the second via part 223-3 may be provided between an edge region and a central region of the first pad part 222. In other words, the second via part 223-3 may be annular in the vertical direction (i.e., the third direction D3).

Referring to FIG. 5C, the second via part 223-4 of the under-bump pad 220 according to an embodiment of the present technology may have an arch shape when viewed in plan. The second via part 223-4 may be provided in plural, and a pair of second via parts 223-4 may be laterally symmetrical in the first direction D1. Another pair of second via parts 223-4 may be vertically symmetrical in the second direction D2. In other words, when viewed from the top down (i.e., along the third direction D3), the second via part 223-4 may be arch shaped. There may be a plurality of arch shaped second via parts 223-4. In some embodiments there may be four arch shaped second via parts 223-4 arranged in rotational symmetry about a center point C. The angle of the rotational symmetry may be 90 degrees. The arc angles of the arches of the arch shaped second via parts 223-4 may be 90 degrees. Furthermore, each of the plurality of arch shaped second via parts 223-4 may be entirely overlapped by the first pad part 222.

Referring to FIG. 5D, the second via part 223-5 of the under-bump pad 220 according to an embodiment of the present technology may have a theta (Q) shape when viewed in plan. In other words, when viewed from the top down (i.e., along the third direction D3), the second via part 223-5 may be annular and shaped like a circle with a bar running from a first point on the circumference of the circle to a second point on the circumference of the circle directly opposite the first point. The second via part 223-5 may be provided in singular.

Referring to FIG. 5E, the second via part 223-6 of the under-bump pad 220 according to an embodiment of the present technology may have a spiral shape when viewed in plan. In other words, when viewed from the top down (i.e., along the third direction D3), the second via part 223-6 may have a spiral. The second via part 223-6 may be provided in singular.

A semiconductor package according to some embodiments of the present technology may include an under-bump pad on a bottom surface of a redistribution substrate. The under-bump pad may include a first pad part, a second pad part on the first pad part, and a via part that connects the first pad part and the second pad part to each other. A width of the second pad part may be greater than that of the first pad part. Thus, even when a stress-inducing crack is vertically propagated after a connection terminal is attached to the under-bump pad, the stress may be alleviated through the second pad part to block the crack propagation.

In addition, as the second pad part integrally extends in a horizontal direction (i.e., in the first direction D1) on the first pad part and the via part, the second pad part may be covered with a wiring dielectric layer having a smooth shape without undulation. As a result, wiring patterns and circuit patterns may be stably formed on the under-bump pad and the wiring dielectric layer.

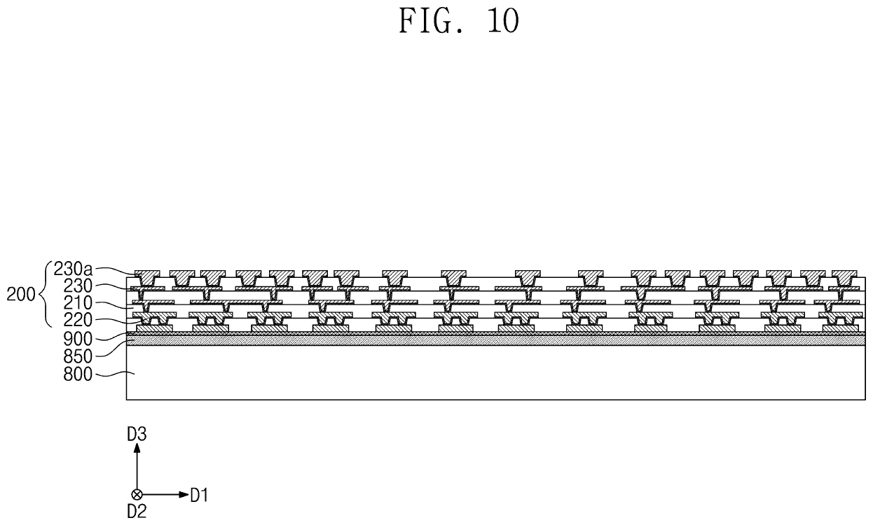

FIGS. 6, 7, 8, 9, and 10 illustrate cross-sectional views showing a method of fabricating a semiconductor package according to some embodiments of the present technology.

Referring to FIGS. 3A and 6, there may be provided a carrier substrate 800 and an adhesive member 850 on the carrier substrate 800. The carrier substrate 800 may be a dielectric substrate including glass or polymer, or may be a conductive substrate including metal. The adhesive member 850 may include a glue tape.

A seed layer 900 may be formed on the adhesive member 850. The seed layer 900 may include at least one selected from copper, titanium, tungsten, and nickel. A patterning process may be performed to form a first photoresist pattern PR1 on the adhesive member 850. The first photoresist pattern PR1 may define a space where a first pad part 222 of an under-bump pad 220 will be formed. Afterwards, a first pad part 222 may be formed by performing an electroplating process in which the seed layer 900 is used as an electrode. Then, the first photoresist pattern PR1 may be removed.

Referring to FIGS. 3A and 7, a wiring dielectric layer 210 may be formed to cover the seed layer 900 and the first pad part 222. The wiring dielectric layer 210 may be formed by coating on the seed layer 900 an organic material such as photo-imageable dielectric (PID). Thereafter, the wiring dielectric layer 210 may be patterned to form a plurality of openings OP. The patterning process may be carried out until a top surface of the first pad part 222 is exposed. The plurality of openings OP may define a space where a second via part 223 of an under-bump pad 220 will be formed.

Referring to FIGS. 3A, 8, and 9 a patterning process may be performed to form a second photoresist pattern PR2 on the wiring dielectric layer 210. The second photoresist pattern PR2 may define a space where a second pad part 224 of an under-bump pad 220 will be formed on the opening OP.

A first seed pattern 223a may be formed on bottom and inner lateral surfaces OPB, OPS of the opening OP, and a second seed pattern 224a may be formed on a top surface of the wiring dielectric layer 210. The first seed pattern 223a and the second seed pattern 224a may be integrally connected into a single unitary piece. A first conductive pattern 223b and a second conductive pattern 224b may be formed by performing an electroplating process in which each of the first and second seed patterns 223a, 224a is used as an electrode. The first conductive pattern 223b may be formed on the first seed pattern 223a and the second conductive pattern 224b may be formed on the second seed pattern 224a. As a result, a second via part 223 may be formed which includes the first seed pattern 223a and the first conductive pattern 223b, and a second pad part 224 may be formed which includes the second seed pattern 224a and the second conductive pattern 224b.

The second via part 223 and the second pad part 224 may be integrally connected into a single unitary piece. The formation of the second via part 223 and the second pad part 224 may form an under-bump pad 220 that includes the first pad part 222, the second pad part 224, and the second via part 223. Then, the second photoresist pattern PR2 may be removed.

Referring to FIGS. 3A and 10, a wiring dielectric layer 210 and a wiring pattern 230 may be formed on the under-bump pad 220. The formation of the wiring dielectric layer 210 and the formation of the wiring patterns 230, 230a may be repeatedly performed. Thus, a redistribution substrate 200 may be formed which includes the under-bump pad 220, the stacked wiring dielectric layers 210, and the stacked wiring patterns 230.

Referring back to FIG. 2, a chip stack 400 and a logic chip 600 may be mounted on the redistribution substrate 200. A second molding layer MD2 may be formed cover a top surface of the redistribution substrate 200, a lateral surface 400S of the chip stack 400, and a lateral surface 600S of the logic chip 600.

The carrier substrate 800, the adhesive member 850, and the seed layer 900 may be removed. After that, a first connection terminal 150 may be attached to the under-bump pad 220 to connect the redistribution substrate 200 and the package substrate 100 to each other, therefore fabricating a semiconductor package 1 according to some embodiments of the present technology.

A semiconductor package according to some embodiments of the present technology may include an under-bump pad on a bottom surface of a redistribution substrate. The under-bump pad may include a first pad part, a second pad part on the first pad part, and a via part that connects the first pad part and the second pad part to each other. A width of the second pad part may be greater than that of the first pad part. Thus, even when a stress-inducing crack vertically propagates after a connection terminal is attached to the under-bump pad, the stress may be alleviated through the second pad part to block the crack propagation.

Although the present inventions have been described in connection with some embodiments of the present technology illustrated in the accompanying drawings, it will be understood to those skilled in the art that various changes and modifications may be made without departing from the technical spirit and essential feature of the present technology. It will be apparent to those skilled in the art that various substitution, modifications, and changes may be thereto without departing from the scope and spirit of the present technology.

What is claimed is:

1. A semiconductor package, comprising:
a redistribution substrate; and
a semiconductor chip on the redistribution substrate;
wherein the redistribution substrate comprises an under-bump pad on a bottom surface of the redistribution substrate;
wherein the under-bump pad comprises:
a first pad part;
a second pad part on the first pad part; and
a via part that protrudes from the second pad part and contacts the first pad part;
wherein the first pad part has a first width in a first direction parallel to a top surface of the redistribution substrate;
wherein the second pad part has a second width in the first direction; and
wherein the second width is greater than the first width.

2. The semiconductor package of claim 1, wherein the second width is 1.1 times to 2 times the first width.

3. The semiconductor package of claim 1, wherein:
the first width is in a range of 80 μm to 110 μm; and
the second width is in a range of 88 μm to 220 μm.

4. The semiconductor package of claim 1, further comprising:
a plurality of the via parts protruding from the second pad part in a vertical direction; and
wherein the first pad part entirely overlaps each of the plurality of via parts in the vertical direction.

5. The semiconductor package of claim 1, wherein, the via part is annular in the vertical direction.

6. The semiconductor package of claim 1, wherein, when viewed in plan, the via part has a theta (O) shape and overlaps the first pad part in a vertical direction.

7. A semiconductor package, comprising:
a redistribution substrate; and
a semiconductor chip on the redistribution substrate;
wherein the redistribution substrate comprises:
a plurality of dielectric layers;
a plurality of wiring patterns in the dielectric layer; and
an under-bump pad on a bottom surface of the redistribution substrate;
wherein the wiring patterns comprise:
a line part; and
a first via part that protrudes from the line part;
wherein the under-bump pad comprises:
a first pad part;
a second pad part on the first pad part; and
a second via part between the first pad part and the second pad part,
wherein the second pad part is in contact with the first via part;
wherein a thickness of the first pad part is greater than a thickness of the line part;
wherein the first via part has a first via part width in a first direction parallel to a top surface of the redistribution substrate;
wherein the second via part has a second via part width in the first direction; and
wherein the second via part width is greater than the first via part width.

8. The semiconductor package of claim 7, wherein the thickness of the first pad part is greater than a thickness of the second pad part.

9. The semiconductor package of claim 8, wherein:
the thickness of the line part is in a range of 2 μm to 4 μm;
the thickness of the first pad part is in a range of 4 μm to 10 μm; and
the thickness of the second pad part is in a range of 3 μm to 5 μm.

10. The semiconductor package of claim 7, wherein:
the first via part width is in a range of 4 μm to 8 μm; and
the second via part width is in a range of 15 μm to 20 μm.

11. The semiconductor package of claim 7, wherein a sum of the thickness of the first pad part and a height of the second via part is substantially the same as a thickness of the dielectric layer.

12. The semiconductor package of claim 7, wherein
the second via part penetrates a lowermost one of the plurality of dielectric layers, and
the second pad part is on a top surface of the lowermost dielectric layer.

13. The semiconductor package of claim 7, wherein a height of the second via part is in a range of 3 μm to 5 μm.

14. A semiconductor package, comprising:
a package substrate;
a redistribution substrate on the package substrate;
a chip stack on the redistribution substrate; and
a logic chip on the redistribution substrate and spaced apart in a first direction from the chip stack, the first direction being parallel to a top surface of the package substrate;
wherein the redistribution substrate comprises:
a plurality of dielectric layers;
a plurality of wiring patterns in the plurality of dielectric layers; and
a plurality of under-bump pads spaced apart in the first direction from each other on a bottom surface of the redistribution substrate;
wherein the wiring patterns comprise:
a line part; and
a first via part that protrudes from the line part;
wherein each of the under-bump pads comprises:
a first pad part;
a second pad part on the first pad part; and
a second via part that protrudes from the second pad part and contacts the first pad part;
wherein a distance in the first direction between the first pad parts is greater than a distance in the first direction between the second pad parts.

15. The semiconductor package of claim 14, wherein, the first pad part is entirely overlapped by the second pad part.

16. The semiconductor package of claim 15, wherein:
at least one of the wiring patterns comprises a plurality of first via parts; and
each of the first via parts is in contact with the second pad part of the under-bump pad.

17. The semiconductor package of claim 14, wherein the first pad part is in contact with the first via part.

18. The semiconductor package of claim 14, wherein:
a thickness of the line part is in a range of 2 μm to 4 μm;
a thickness of the first pad part is in a range of 4 μm to 10 μm; and
a thickness of the second pad part is in a range of 3 μm to 5 μm.

19. The semiconductor package of claim 14, wherein, when viewed in plan, a lateral surface of the second pad part surrounds a lateral surface of the first pad part.

20. The semiconductor package of claim 14, further comprising a connection terminal on the first pad part.
